(19) United States
(12) Patent Application Publication
(10) Pub. No.: US 2025/0318100 A1
(43) Pub. Date: Oct. 9, 2025

(54) 3-TRANSISTOR FOOTPRINT STACKED SRAM

(71) Applicant: International Business Machines Corporation, Armonk, NY (US)

(72) Inventors: Chen Zhang, Santa Clara, CA (US); Shay Reboh, Guilderland, NY (US); Ruilong Xie, Niskyuna, NY (US); Debarghya Sarkar, Latham, NY (US)

(21) Appl. No.: 18/625,301

(22) Filed: Apr. 3, 2024

(51) Int. Cl. H10B 10/00

(52) U.S. Cl. CPC H10B 10/125

(57) ABSTRACT

Embodiments of the present disclosure are directed to processing methods and resulting structures for providing three-transistor (3T) footprint stacked SRAMs. In a non-limiting embodiment, an SRAM bit cell includes a first inverter positioned at a first obtuse corner of a parallelogram. The first inverter includes a first pull-up transistor (PU) vertically stacked over a first pull-down transistor (PD). The SRAM bit cell includes a second inverter positioned at a second obtuse corner of the parallelogram. The second inverter includes a second PU vertically stacked over a second PD. A first pass-gate (PG) is positioned at a first acute corner of the parallelogram and a second PG is positioned at a second acute corner of the parallelogram.

### BACKGROUND

The present disclosure generally relates to semiconductor technology, and more particularly to a semiconductor structure including a three-transistor (3T) footprint stacked field effect transistor (FET) with a static random access memory (SRAM) design.

SRAM is a type of random access memory (RAM) that uses latch circuitry (flip-flop) to store each bit. A typical SRAM cell is made up of six FETs. Each bit in a conventional SRAM is stored on four of the transistors that form two cross-coupled inverters. This storage cell has two stable states which are used to denote 0 and 1. Two additional access transistors serve to control the access to a storage cell during read and write operations. In addition to such six-transistor (6T) SRAM architectures, other kinds of SRAM chips use 4, 8, 10 (4T, 8T, 10T SRAM), or more transistors per bit.

Monolithic and sequential stacking of transistors are attractive architectures for future complementary metal oxide semiconductor (CMOS) scaling, and potentially for ultimately scaled technology. By directly stacking one type of FET (e.g., an n-type FET) over another type (e.g., a p-type FET), significant area scaling can be achieved. For example, in a stacked SRAM architecture, the pull-up (PU) transistors can be vertically stacked on top of the pull-down (PD) transistors of the cross-coupled inverter pair, or vice versa. This vertical arrangement allows the stacked SRAM cell to have a smaller footprint (4T) as compared to a traditional 6T SRAM cell, which, due to the presence of two half-dummy PFET areas (that is, areas within the footprint that could include two transistors, but only include one) at the pass-gates (PG), actually require an eight-transistor footprint.

### SUMMARY

Embodiments of the disclosure are directed to a method for forming a static random access memory (SRAM) bit cell. A non-limiting example of the method includes forming a first inverter positioned at a first obtuse corner of a parallelogram. The first inverter includes a first pull-up transistor (PU) vertically stacked over a first pull-down transistor (PD). The method includes forming a second inverter positioned at a second obtuse corner of the parallelogram. The second inverter includes a second PU vertically stacked over a second PD. The method includes forming a first pass-gate (PG) positioned at a first acute corner of the parallelogram and forming a second PG positioned at a second acute corner of the parallelogram.

Embodiments of the disclosure are directed to a three-transistor (3T) footprint stacked SRAM bit cell. A non-limiting example of the bit cell includes a first inverter positioned at a first obtuse corner of a parallelogram. The first inverter includes a first PU vertically stacked over a first PD. The SRAM bit cell includes a second inverter positioned at a second obtuse corner of the parallelogram. The second inverter includes a second PU vertically stacked over a second PD. A first PG is positioned at a first acute corner of the parallelogram and a second PG is positioned at a second acute corner of the parallelogram.

Embodiments of the disclosure are directed to a method for forming a semiconductor device. A non-limiting example of the method includes forming a first SRAM bit cell having a first bit cell type. The first bit cell type includes a first pair of pass-gates (PGs) positioned in a top level of the first SRAM bit cell. The method includes forming a second SRAM bit cell having a second bit cell type. The second bit cell type includes a second pair of PGs positioned in a bottom level of the second SRAM bit cell. The first SRAM bit cell and the second SRAM bit cell are immediately adjacent bit cells. A pass-gate of the first SRAM bit cell and a pass-gate of the second SRAM bit cell are vertically stacked in a same pass-gate area such that the first SRAM bit cell and the second SRAM bit cell partially overlap in a 3T footprint.

Embodiments of the disclosure are directed to a semiconductor device. A non-limiting example of the semiconductor device includes a first SRAM bit cell having a first bit cell type. The first bit cell type includes a first pair of pass-gates (PGs) positioned in a top level of the first SRAM bit cell. The semiconductor device includes a second SRAM bit cell having a second bit cell type. The second bit cell type includes a second pair of PGs positioned in a bottom level of the second SRAM bit cell. The first SRAM bit cell and the second SRAM bit cell are immediately adjacent bit cells. A pass-gate of the first SRAM bit cell and a pass-gate of the second SRAM bit cell are vertically stacked in a same pass-gate area such that the first SRAM bit cell and the second SRAM bit cell partially overlap in a 3T footprint.

Embodiments of the disclosure are directed to a 3T footprint stacked SRAM bit cell. A non-limiting example of the bit cell includes a first inverter positioned at a first obtuse corner of a parallelogram. The first inverter includes a first PD vertically stacked over a first PU. The SRAM bit cell includes a second inverter positioned at a second obtuse corner of the parallelogram. The second inverter includes a second PD vertically stacked over a second PU. A first PG is positioned at a first acute corner of the parallelogram and a second PG is positioned at a second acute corner of the parallelogram.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a top-down view of a parallelogram shaped stacked SRAM bit cell design according to one or more embodiments;

FIG. 2 is a top-down view of a circuit design layout for a parallelogram shaped stacked SRAM bit cell design according to one or more embodiments;

FIG. 3 is an alternative top-down view of the circuit design layout of FIG. 2 according to one or more embodiments;

FIG. 4 is an alternative top-down view of the circuit design layout of FIG. 2 according to one or more embodiments;

FIG. 5 is an alternative top-down view of the circuit design layout of FIG. 2 according to one or more embodiments;

FIG. 6 is a cross-sectional view of the circuit design layout of FIG. 2 along the line A-A according to one or more embodiments;

FIG. 7 is an alternative cross-sectional view of the circuit design layout of FIG. 2 along the line A-A according to one or more embodiments;

FIG. 8 depicts a flow diagram illustrating a method according to one or more embodiments; and

FIG. 9 depicts a flow diagram illustrating a method according to one or more embodiments.

The diagrams depicted herein are illustrative. There can be many variations to the diagram or the operations described therein without departing from the spirit of the disclosure. For instance, the actions can be performed in a differing order or actions can be added, deleted or modified.

In the accompanying figures and following detailed description of the described embodiments of the disclosure, the various elements illustrated in the figures are provided with two or three-digit reference numbers. With minor exceptions, the leftmost digit(s) of each reference number correspond to the figure in which its element is first illustrated.

### DETAILED DESCRIPTION

According to an aspect of the disclosure, there is provided a method for providing a static random access memory (SRAM) bit cell. A non-limiting example of the method includes forming a first inverter positioned at a first obtuse corner of a parallelogram. The first inverter includes a first pull-up transistor (PU) vertically stacked over a first pull-down transistor (PD). The method includes forming a second inverter positioned at a second obtuse corner of the parallelogram. The second inverter includes a second PU vertically stacked over a second PD. The method includes forming a first pass-gate (PG) positioned at a first acute corner of the parallelogram and forming a second PG positioned at a second acute corner of the parallelogram. Advantageously, forming an SRAM bit cell in this manner allows for overlapping with adjacent bit cells, thereby providing an aggregate 3T footprint.

In some embodiments, the method includes forming a supply voltage (VDD) line positioned on a frontside of the SRAM bit cell and forming a source supply voltage (VSS) line positioned on a backside of the SRAM bit cell. This serves as a physical signature of the manufacturing method described herein.

In some embodiments, the first PU and the second PU are on a top level of the SRAM bit cell and the first PD and the second PD are on a bottom level below the top level. This allows for a pair of SRAM bit cells to partially overlap (at a shared PG area) within an aggregate 3T footprint.

In some embodiments, the method includes forming a word line (WL) and forming a bit line (BL). In some embodiments, the first PG and the second PG are on the top level and the WL and BL are positioned on the frontside of the SRAM bit cell. In some embodiments, the first PG and the second PG are on the bottom level and the WL and BL are positioned on the backside of the SRAM bit cell. In these configurations, the bit cell is compatible with PGs having different polarities.

Embodiments of the disclosure are directed to a three-transistor (3T) footprint stacked SRAM bit cell. A non-limiting example of the bit cell includes a first inverter positioned at a first obtuse corner of a parallelogram. The first inverter includes a first PU vertically stacked over a first PD. The SRAM bit cell includes a second inverter positioned at a second obtuse corner of the parallelogram. The second inverter includes a second PU vertically stacked over a second PD. A first PG is positioned at a first acute corner of the parallelogram and a second PG is positioned at a second acute corner of the parallelogram.

In some embodiments, a supply voltage (VDD) line is positioned on a frontside of the SRAM bit cell and a source supply voltage (VSS) line is positioned on a backside of the SRAM bit cell. The VDD and VSS lines can be used to change a state of the SRAM bit cell (e.g., from 0 to 1).

In some embodiments, the first PU and the second PU are on a top level of the SRAM bit cell and the first PD and the second PD are on a bottom level below the top level. This allows for the SRAM bit cell to partially overlap (at the PG area) with other bit cells.

In some embodiments, the SRAM bit cell includes a WL and a BL. In some embodiments, the first PG and the second PG are on the top level and the WL and BL are positioned on the frontside of the SRAM bit cell. In some embodiments, the first PG and the second PG are on the bottom level and the WL and BL are positioned on the backside of the SRAM bit cell. In these configurations, the bit cell is compatible with PGs having different polarities.

Embodiments of the disclosure are directed to a method for forming a semiconductor device. A non-limiting example of the method includes forming a first SRAM bit cell having a first bit cell type. The first bit cell type includes a first pair of pass-gates (PGs) positioned in a top level of the first SRAM bit cell. The method includes forming a second SRAM bit cell having a second bit cell type. The second bit cell type includes a second pair of PGs positioned in a bottom level of the second SRAM bit cell. The first SRAM bit cell and the second SRAM bit cell are immediately adjacent bit cells. A pass-gate of the first SRAM bit cell and a pass-gate of the second SRAM bit cell are vertically stacked in a same pass-gate area such that the first SRAM bit cell and the second SRAM bit cell partially overlap in a 3T footprint.

In some embodiments, each of the first SRAM bit cell and the second SRAM bit cell includes a first inverter positioned at a first obtuse corner of a parallelogram. The first inverter includes a first PU vertically stacked over a first PD. A second inverter is positioned at a second obtuse corner of the parallelogram. The second inverter includes a second PU vertically stacked over a second PD. A first PG is positioned at a first acute corner of the parallelogram and a second PG is positioned at a second acute corner of the parallelogram. This configuration allows the first PG and second PG to partially overlap with PGs from adjacent bit cells.

In some embodiments, the first pair of PGs positioned in the top level of the first SRAM bit cell have a first polarity, and the second pair of PGs positioned in the bottom level of the second SRAM bit cell have a second polarity opposite the first polarity. This configuration enables split-polarity architectures.

In some embodiments, the first SRAM bit cell includes a first WL and a first BL positioned on a frontside of the first SRAM bit cell, and the second SRAM bit cell includes a second WL and a second BL positioned on a backside of the second SRAM bit cell. In these configurations, the bit cells are compatible with PGs having different polarities.

In some embodiments, the first pair of PGs positioned in the top level of the first SRAM bit cell and the second pair of PGs positioned in the bottom level of the second SRAM bit cell have a same polarity. In some embodiments, a WL is positioned on a frontside of the semiconductor device, a first BL is positioned on the frontside of the semiconductor device, and a second BL is positioned on a backside of the semiconductor device. This configuration is compatible with single-polarity architectures.

Embodiments of the disclosure are directed to a semiconductor device. A non-limiting example of the semiconductor device includes a first SRAM bit cell having a first bit cell type. The first bit cell type includes a first pair of pass-gates (PGs) positioned in a top level of the first SRAM bit cell. The semiconductor device includes a second SRAM bit cell having a second bit cell type. The second bit cell type includes a second pair of PGs positioned in a bottom level of the second SRAM bit cell. The first SRAM bit cell and the second SRAM bit cell are immediately adjacent bit cells. A pass-gate of the first SRAM bit cell and a pass-gate of the second SRAM bit cell are vertically stacked in a same pass-gate area such that the first SRAM bit cell and the second SRAM bit cell partially overlap in a 3T footprint.

In some embodiments, each of the first SRAM bit cell and the second SRAM bit cell includes a first inverter positioned at a first obtuse corner of a parallelogram. The first inverter includes a first PU vertically stacked over a first PD. A second inverter is positioned at a second obtuse corner of the parallelogram. The second inverter includes a second PU vertically stacked over a second PD. A first PG is positioned at a first acute corner of the parallelogram and a second PG is positioned at a second acute corner of the parallelogram. This configuration allows the first PG and second PG to partially overlap with PGs from adjacent bit cells.

In some embodiments, the first pair of PGs positioned in the top level of the first SRAM bit cell have a first polarity, and the second pair of PGs positioned in the bottom level of the second SRAM bit cell have a second polarity opposite the first polarity. This configuration enables split-polarity architectures.

In some embodiments, the first SRAM bit cell includes a first WL and a first BL positioned on a frontside of the first SRAM bit cell, and the second SRAM bit cell includes a second WL and a second BL positioned on a backside of the second SRAM bit cell. In these configurations, the bit cells are compatible with PGs having different polarities.

In some embodiments, the first pair of PGs positioned in the top level of the first SRAM bit cell and the second pair of PGs positioned in the bottom level of the second SRAM bit cell have a same polarity. In some embodiments, a WL is positioned on a frontside of the semiconductor device, a first BL is positioned on the frontside of the semiconductor device, and a second BL is positioned on a backside of the semiconductor device. This configuration is compatible with single-polarity architectures.

Embodiments of the disclosure are directed to a 3T footprint stacked SRAM bit cell. A non-limiting example of the bit cell includes a first inverter positioned at a first obtuse corner of a parallelogram. The first inverter includes a first PD vertically stacked over a first PU. The SRAM bit cell includes a second inverter positioned at a second obtuse corner of the parallelogram. The second inverter includes a second PD vertically stacked over a second PU. A first PG is positioned at a first acute corner of the parallelogram and a second PG is positioned at a second acute corner of the parallelogram.

In some embodiments, a VDD line is positioned on a frontside of the SRAM bit cell and a VSS line is positioned on a backside of the SRAM bit cell. The VDD and VSS lines can be used to change a state of the SRAM bit cell (e.g., from 0 to 1).

In some embodiments, the first PD and the second PD are on a top level of the SRAM bit cell and the first PU and the second PU are on a bottom level below the top level. This allows for the SRAM bit cell to partially overlap (at the PG area) with other bit cells.

In some embodiments, the SRAM bit cell includes a WL and a BL. In some embodiments, the first PG and the second PG are on the top level and the WL and BL are positioned on the frontside of the SRAM bit cell. In some embodiments, the first PG and the second PG are on the bottom level and the WL and BL are positioned on the backside of the SRAM bit cell. In these configurations, the bit cell is compatible with PGs having different polarities.

It is understood in advance that although example embodiments of the disclosure are described in connection with a particular transistor architecture, embodiments of the disclosure are not limited to the particular transistor architectures or materials described in this specification. Rather, embodiments of the present disclosure are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present disclosure, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

Static random access memory (SRAM) area scaling has been a big challenge using non-stacked transistor technologies. As discussed previously, for a typical 6-transistor SRAM, the footprint is approximately 8 transistors (8T), including two pull-up transistors (2 PUs), two pull-down transistors (2 PDs), two pass-gate transistors (2 PGs), and two half-dummy PFET areas above the PGs that are electrically isolated via a gate-cut. Stacking the transistors in a so-called stacked SRAM architecture can offer a smaller footprint than traditional 6T SRAM cells having 8T footprints. This can be achieved, for example, by moving PU transistors to the top of PD transistors in a two-layer configuration. The result is a reduction in footprint to 4 transistors, often referred to as “4T” stacked SRAMs. In other words, current stacked SRAM architectures can offer a footprint reduction of roughly 50 percent (e.g., from 8T to 4T).

In current two-layer 4T stacked SRAM layouts, SRAM bit cells (each including a 4T stacked SRAM) are positioned end-to-end in one or more columns and the PG transistors for each bit cell are positioned along the bottom layer. The space above the two PG transistors (that is, the half-dummy PFET areas) for each bit cell is used for the MOL, as those areas are otherwise unused. Further improvements in area scaling have been limited.

This disclosure introduces a three-transistor (3T) footprint stacked SRAM architecture and methods of fabricating the same. Rather than using the half-dummy PFET areas over the PGs for the less-critical MOL, a parallelogram shaped stacked SRAM bit cell design is proposed to re-purpose the half-dummy PFET areas so that those areas can include another transistor. In some embodiments, the PGs for each bit cell are positioned near the acute corners of a parallelogram and the inverters (a vertically integrated PU/PD) sit on the obtuse corners. Advantageously, in this configuration, adjacent bit cells in a column utilize the same PG area. In particular, one bit cell uses the PG FET in the bottom layer and the adjacent bit cell(s) use the PG FET in the top layer. In other words, this disclosure provides an SRAM architecture that utilizes wasted PG space to achieve an effective 3T footprint bit cell design. As used herein, an “effective 3T footprint” refers to the fact that, while each individual bit cell still includes a 4T footprint, the PG regions are shared by adjacent bit cells to give an effective 3T footprint, in the aggregate. Restated, an “effective 3T footprint” refers to a 4T footprint where the PG regions between adjacent bit cells overlap.

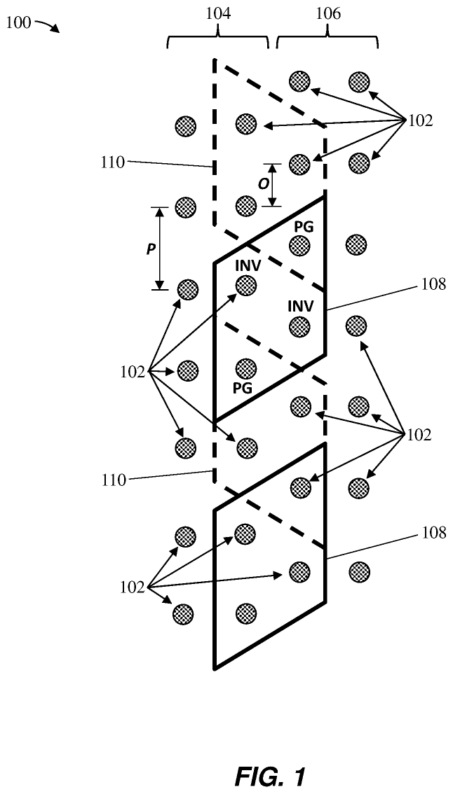

Turning now to a more detailed description of fabrication operations and resulting structures according to aspects of the disclosure, FIG. 1 depicts a top-down view of a parallelogram shaped stacked SRAM bit cell design 100 according to one or more embodiments of the disclosure. The parallelogram shaped stacked SRAM bit cell design 100 includes a set of transistor channels 102, configured and arranged as shown. Transistor channels 102 denote the locations of the intersections between gates and active regions in the parallelogram shaped stacked SRAM bit cell design 100.

In some embodiments, the transistor channels 102 are arranged in an array-like pattern that includes a first bank 104 and a second bank 106. In some embodiments, the first bank 104 includes two columns of transistor channels 102, and the second bank 106 includes two columns of transistor channels 102 offset from the columns of the first bank 104. In some embodiments, adjacent pairs of the transistor channels 102 are separated by a same pitch P. While not meant to be particularly limited, the pitch P can range from roughly 10 nanometers to 100 nanometers or more, for example, from 20 nanometers to 60 nanometers. In some embodiments, the second bank 106 is offset from the first bank 104 by an offset distance O. In some embodiments, the offset distance O is one half of the pitch P (as shown), although other pitch and offset configurations are within the contemplated scope of this disclosure.

In some embodiments, the parallelogram shaped stacked SRAM bit cell design 100 includes a first bit cell type 108 and a second bit cell type 110. In some embodiments, the first bit cell type 108 and the second bit cell type 110 are SRAM bit cells, each having two PMOS PUs and two NMOS PDs (vertically stacked to define a pair of inverters “INV” as previously described), as well as two PGs. In some embodiments, the first bit cell type 108 and the second bit cell type 110 alternate within the parallelogram shaped stacked SRAM bit cell design 100. While shown having four bit cells (two of the first bit cell type 108 and two of the second bit cell type 110), this is for convenience and ease of illustration only. It should be understood that the parallelogram shaped stacked SRAM bit cell design 100 can include any number of transistor channels 102 arranged along any number of banks (with each bank offset with respect to adjacent banks), and all such configurations are within the contemplated scope of this disclosure.

In some embodiments, adjacent pairs of the first bit cell type 108 and the second bit cell type 110 partially overlap. In some embodiments, this overlap occurs where each respective bit cell includes a pass-gate. In other words, overlap occurs where the transistor channels 102 denote pass-gates PG. In some embodiments, both the top and bottom FETs in the transistor channels 102 within the intersection of a first bit cell type 108 and a second bit cell type 110 are pass-gates. In some embodiments, the first bit cell type 108 uses one of these pass-gates (e.g., the top PG), and the second bit cell type 110 uses the other pass-gate (e.g., the bottom PG). Observe that this configuration differs from prior stacked SRAM bit cells, which typically include a single PG in each transistor channel (with the remaining slot, typically at the top, used for MOL elements). In some embodiments, the first bit cell type 108 uses top FETs as pass-gates, while the second bit cell type 110 uses bottom FETs as pass-gates, although this is merely a matter of convention. Advantageously, such a design results in an effective 3T footprint, where each bit cell includes two unshared inverters (each a vertical PU/PD stack), a PG shared with the bit cell above, and a PG shared with the bit cell below (as shown). The shared PG elements are effectively 0.5T, resulting in an aggregate 3T bit cell layout. This represents a 62.5 percent reduction in footprint as compared to planar 8T SRAM layouts, and a 25 percent reduction in footprint as compared to prior stacked 4T SRAM layouts.

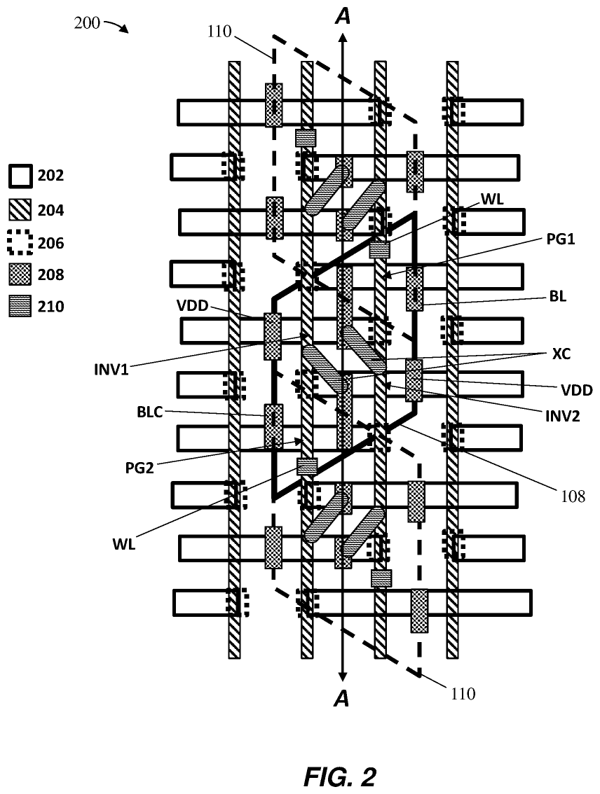

FIG. 2 depicts a top-down view of a circuit design layout 200 for a parallelogram shaped stacked SRAM bit cell design (e.g., the parallelogram shaped stacked SRAM bit cell design 100 of FIG. 1) according to one or more embodiments of the disclosure. In particular, FIG. 2 illustrates the circuit design layout 200 from over the frontside MOL elements of the SRAM architecture. As shown in FIG. 2, the circuit design layout 200 includes a number of SRAM bit cells, in particular, a first bit cell type 108 alternating with a second bit cell type 110 (refer to FIG. 1). Each bit cell includes a first inverter INV1, a second inverter INV2, a first pass-gate PG1, and a second pass-gate PG2. It should be noted that the circuit design layout 200 shown in FIG. 2 is for a configuration where both the inverter stack and PG stack (see below) are positioned such that the pFETs are on the top layer and the nFETs are on the bottom layer. Alternatively, the circuit design layout 200 can be constructed such that the pFETs are on the bottom layer and the nFETs are on the top layer, but this separate construction is omitted for clarity. Both configurations are within the contemplated scope of this disclosure.

The circuit design layout 200 (an SRAM cell) is implemented using a cross-coupled inverter pair that includes the first inverter INV1 and the second inverter INV2. In some embodiments, each inverter INV1, INV2 is connected to the output of the other inverter. Thus, the cross-coupled inverter pair INV1, INV2 forms a bistable latch (with two stable states) that can store a single bit of data and serves as the storage element of the respective SRAM cell. The two stable states of the cross-coupled inverter pair represent the two binary values (0 and 1) that can be stored in the respective SRAM cell. When one inverter output is high (logic 1), the other inverter output is low (logic 0), and vice versa. Thus, the two outputs of the cross-coupled inverters can be referred to as storage nodes.

The first inverter INV1 and the second inverter INV2 each include a PMOS “PU” transistor and an NMOS “PD” transistor, with their gates connected to the output of the other inverter via a pair of cross-coupled contacts “XC”. In some embodiments, the PU transistors can be vertically stacked on top of the PD transistors, or vice versa. The term “pull-up transistor” in an SRAM cell refers to the PMOS (P-channel MOSFET) transistor that is responsible for pulling the storage node up to the logic high level (VDD or supply voltage) when the cell is storing a logic “1”. In some embodiments, the source terminal of the PU transistor is connected to the supply voltage (VDD), and the drain terminal is connected to one of the respective storage nodes (the other storage node than connected to the PD transistor). When the storage node needs to be charged to represent a logic “1”, the PU transistor can be turned on by applying the appropriate gate voltage to the respective pass-gate (PG1 or PG2). This allows the current to flow from the VDD supply through the PU transistor, effectively “pulling up” the voltage level of the storage node to VDD. Conversely, the term “pull-down transistor” in an SRAM cell refers to the NMOS (N-channel MOSFET) transistor that is responsible for pulling the storage node down to the logic low level (VSS or source supply voltage, also referred to as GND or ground) when the cell is storing a logic “0”. In some embodiments, the source terminal of the PD transistor is connected to ground (or, more specifically, local ground VSS), and the drain terminal is connected to one of the respective storage nodes (the other storage node than connected to the PU transistor). When the storage node needs to be discharged to represent a logic “0”, the PD transistor can be turned on by applying the appropriate gate voltage to the respective pass-gate (PG2 or PG1). This allows the current to flow from the storage node through the PD transistor to VSS, effectively “pulling down” the voltage level of the storage node to GND.

The first pass-gate PG1 and the second pass-gate PG2 are access transistors that control access to the storage nodes from a pair of complementary bit lines (BL and BLC). In some embodiments, one of PG1 and PG2 is connected to each storage node of the respective cross-coupled inverter pair. The gates of the access transistors PG1, PG2 are connected to the word line (WL) signal. During a read or write operation, PG1 and PG2 are controlled by the WL to allow access to the storage nodes of the inverter pair through the bit lines BL and BLC (also referred to as BL bar). In particular, during a read operation, the differential voltage between the two storage nodes is transferred to the bit lines through the access transistors, allowing downstream sense amplifiers (not separately shown) to detect the stored data. During a write operation, the desired data value is driven onto the bit lines, and the cross-coupled inverter pair is forced into the corresponding state (0 or 1) through the access transistors PG1, PG2, updating the voltage levels of the storage nodes.

To complete the SRAM circuitry, the circuit design layout 200 further includes a plurality of active areas 202 (source/drain regions) arranged in parallel rows and a plurality of gates 204 arranged in parallel columns, configured and arranged as shown. A plurality of single diffusion breaks (SDBs) 206 are positioned at the intersections between the active areas 202 and the gates 204. A plurality of front side contacts 208, 210 ensure electrical continuity between the FEOL devices (e.g., INV1, INV2, PG1, PG2, WL) and frontside MOL elements (e.g., BL, BLC, and the front side contacts 208, 210 themselves).

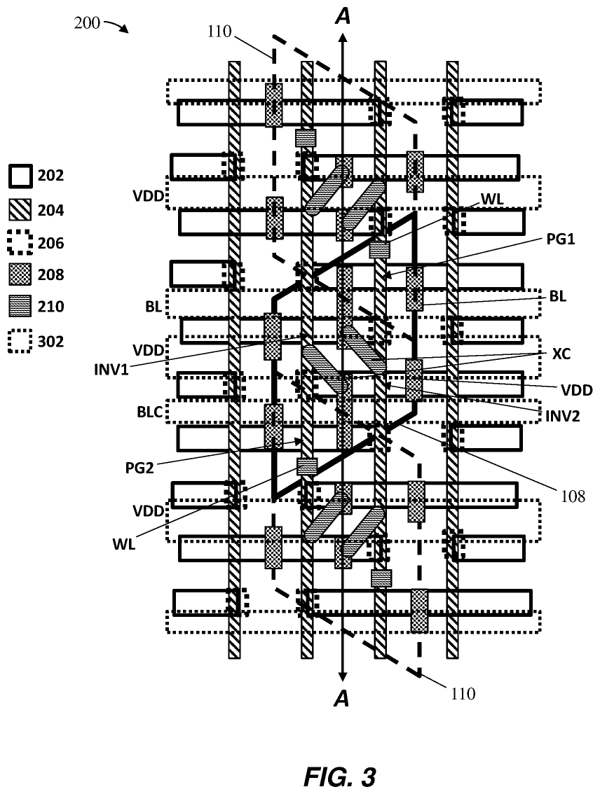

FIG. 3 depicts an alternative top-down view of the circuit design layout 200 of FIG. 2 according to one or more embodiments of the disclosure. In particular, FIG. 3 illustrates the circuit design layout 200 from over the frontside MOL elements and the frontside BEOL elements of the SRAM architecture. As shown in FIG. 3, the circuit design layout 200 further includes a plurality of frontside BEOL elements 302, often referred to as a frontside interconnect and/or as the first frontside metallization layer (or front V0/M1, referring separately to the first via and first metal layer of the interconnect on the frontside of the circuit design layout 200, respectively).

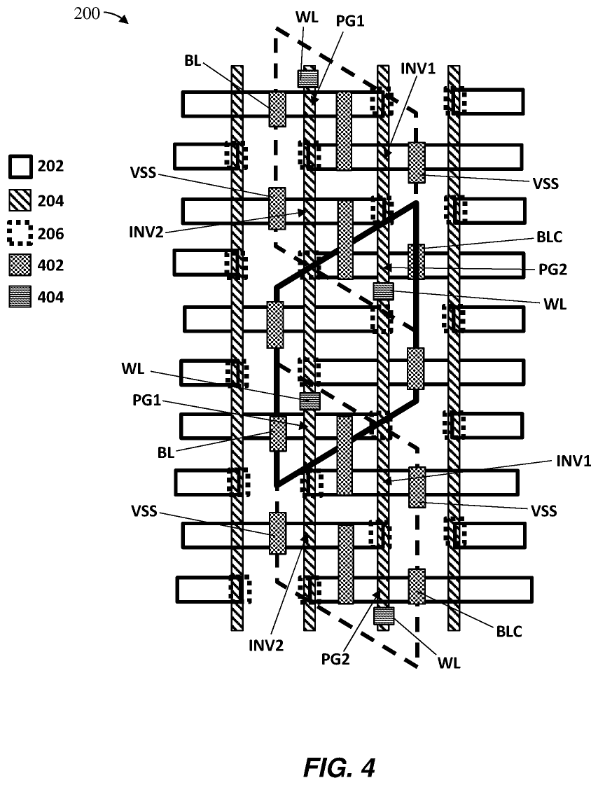

FIG. 4 depicts an alternative top-down view of the circuit design layout 200 of FIG. 2 according to one or more embodiments of the disclosure. In particular, FIG. 4 illustrates the circuit design layout 200 from over the backside MOL elements of the SRAM architecture. As shown in FIG. 4, the circuit design layout 200 further includes a plurality of back side contacts 402, 404 to ensure electrical continuity between the FEOL devices (e.g., INV1, INV2, PG1, PG2, WL) and backside MOL elements (e.g., BL, BLC, and the back side contacts 402, 404 themselves).

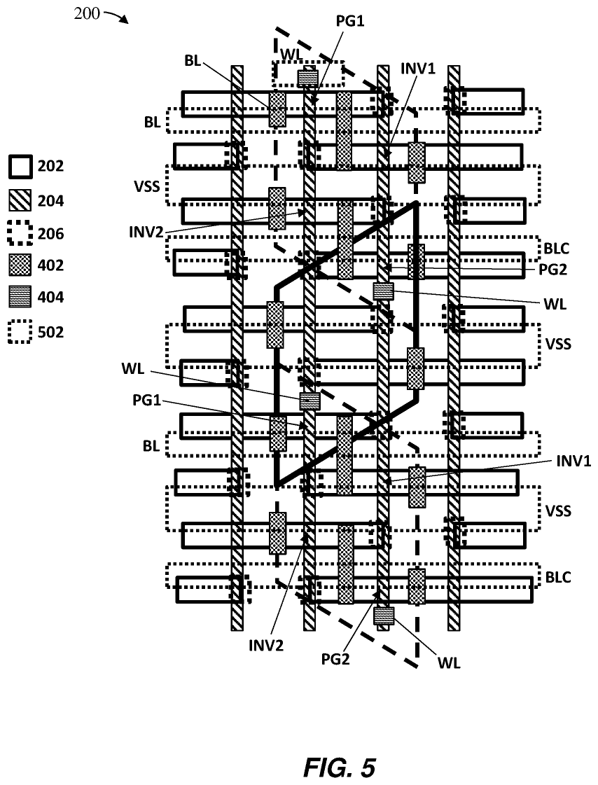

FIG. 5 depicts an alternative top-down view of the circuit design layout 200 of FIG. 2 according to one or more embodiments of the disclosure. In particular, FIG. 5 illustrates the circuit design layout 200 from over the backside MOL elements and the backside BEOL elements of the SRAM architecture. As shown in FIG. 5, the circuit design layout 200 further includes a plurality of backside BEOL elements 502, often referred to as a backside interconnect and/or as the first backside metallization layer (or back V0/M1, referring separately to the first via and first metal layer of the interconnect on the backside of the circuit design layout 200, respectively).

The circuit design layout 200 of the parallelogram shaped stacked SRAM bit cell design 100 offers a number of observable features (physical signatures). First, the first bit cell type 108 and the second bit cell type 110 are arranged as alternating parallelograms, where the positions of the respective obtuse angles (corners) and acute angles (corners) in the first bit cell type 108 are opposite those of the second bit cell type 110 (that is, the alternating parallelograms are mirrored). The pass-gates PG1, PG2 are positioned nearest the acute corners and the inverters INV1, INV2 are positioned nearest the obtuse corners. In addition, adjacent bit cells in a column of the circuit design layout 200 utilize the same PG area, as discussed previously. In short, one of the bit cells uses the PG FET at the bottom and the other uses the PG FET at the top.

Observe from FIGS. 2 to 5 that, in the circuit design layout 200, the VDD and VSS are on different sides of the FETs INV1, INV2, PG1, and PG2 (compare, for example, the VDD placements on FIG. 3 to the VSS placements on FIG. 5). In some embodiments, the bit cells using the bottom PGs are constructed such that the respective WL and BL/BLC run on the back side of the FETs. Conversely, the bit cells using top PGs are constructed such that the respective WL and BL/BLC run on the front side of the FETs (compare, for example, the frontside shown in FIGS. 2 and 3 to the backside shown in FIGS. 4 and 5). In this configuration, the top PG (one of PG1, PG2) and the bottom PG (one of PG2, PG1) have different polarity (as shown). In some embodiments, the top PG and bottom PG have the same polarity. In this configuration, the WL runs on one side of the device while BL/BLC runs on both sides (not separately shown).

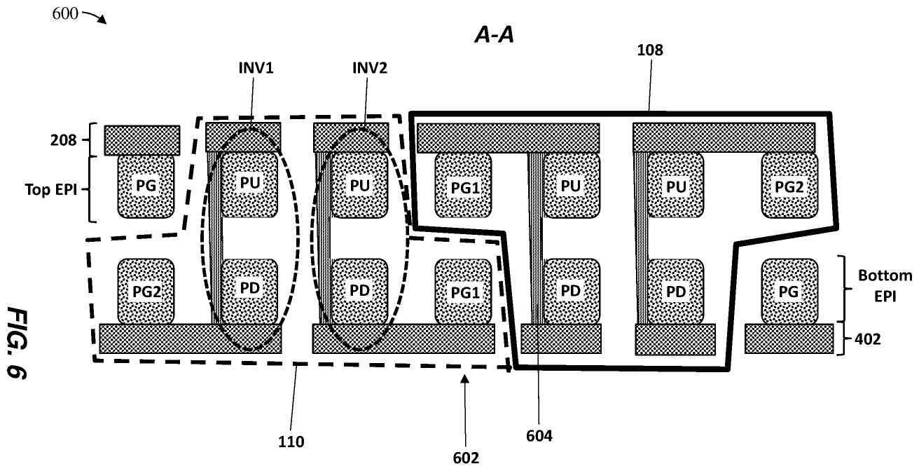

FIG. 6 depicts a cross-sectional view 600 of the circuit design layout 200 of FIG. 2 along the line A-A according to one or more embodiments of the disclosure. As shown in FIG. 6, the first bit cell type 108 and the second bit cell type 110 of the parallelogram shaped stacked SRAM bit cell design 100 (and circuit design layout 200) partially overlap. Specifically, the first bit cell type 108 and the second bit cell type 110 share a common PG region 602.

From the cross-sectional view offered by FIG. 6, it can be readily shown that the total footprint of the first bit cell type 108 and the second bit cell type 110 is lowered due to the overlapping PG region 602. In effect, the first bit cell type 108 and the second bit cell type 110 each only require half of the shared PG region 602. While not separately indicated, the same configuration is possible with upstream/downstream bit cells. The overall result is that each bit cell (alternating between the first bit cell type 108 and the second bit cell type 110) in the circuit design layout 200 only requires a 3T footprint, with 1T required for INV1, 1T required for INV2, and 0.5T required for each of the two shared PG regions 602 (2×0.5T).

As further shown in FIG. 6, in some embodiments, the circuit design layout 200 includes one or more sidewall straps 604 positioned between respective ones of the PU/PD pairs (that is, the inverters). The sidewall straps 604 can be made of a conductive material, thereby shorting the NMOS drain of the respective PD to the PMOS drain of the respective PU.

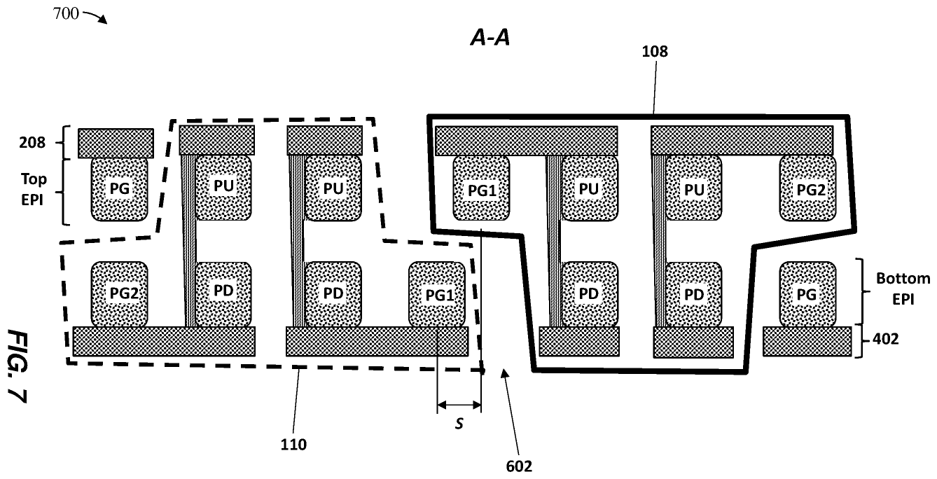

FIG. 7 depicts an alternative cross-sectional view 700 of the circuit design layout 200 of FIG. 2 along the line A-A according to one or more embodiments of the disclosure. As shown in FIG. 7, the first bit cell type 108 and the second bit cell type 110 of the parallelogram shaped stacked SRAM bit cell design 100 (and circuit design layout 200) partially overlap in a similar manner as discussed with respect to FIG. 6. However, in the view 700 the shared PG region 602 is not in complete alignment. In other words, there is some degree of misalignment between the PG1 of the first bit cell type 108 and the PG1 of the second bit cell type 110.

In other words, FIG. 7 illustrates an embodiment where the top and bottom FETs, which serve as the top and bottom PGs of the respective first bit cell type 108 and second bit cell type 110, are not in complete alignment. In some embodiments, the top PG and bottom PG might be shifted by some shift distance S (measured, e.g., as the centerline-to-centerline distance between the respective PGs) due to lithographic and/or other patterning processes. The practical result of such misalignments is that a full 25 percent reduction in SRAM footprint is not realized for the parallelogram shaped stacked SRAM bit cell design 100 described herein. The realized percent reduction in footprint decreases as the shift distance S increases. In some embodiments, the shift distance S is between zero (no shift) and a full offset of approximately one-half the width of the PG region. At the full offset (that is, when the top and bottom PGs are minimally aligned vertically), the footprint reduction is reduced to approximately 15 percent. Thus, the realized percent reduction in footprint for the parallelogram shaped stacked SRAM bit cell design can range from approximately 15 percent to a full 25 percent, depending on the degree of alignment (offset distance S) between the top and bottom PGs.

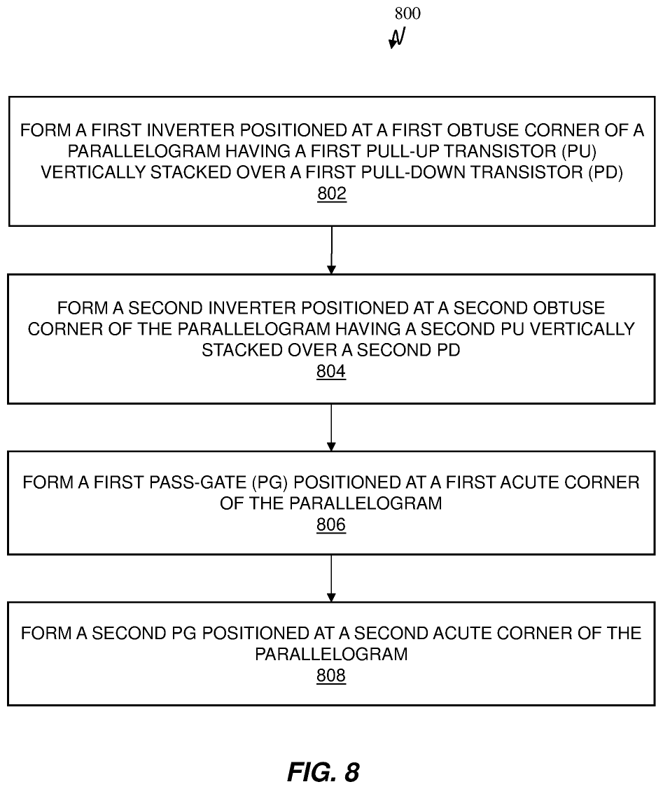

FIG. 8 depicts a flow diagram illustrating a method 800 for forming a three-transistor (3T) footprint stacked SRAM architecture according to one or more embodiments. The method 800 is described in reference to FIGS. 1-7 and may include additional blocks not depicted in FIG. 8. Although depicted in a particular order, the blocks depicted in FIG. 8 can be rearranged, subdivided, and/or combined.

As shown at block 802, the method includes forming a first inverter positioned at a first obtuse corner of a parallelogram. In some embodiments, the first inverter includes a first PU vertically stacked over a first PD.

As shown at block 804, the method includes forming a second inverter positioned at a second obtuse corner of the parallelogram. In some embodiments, the second inverter includes a second PU vertically stacked over a second PD.

As shown at block 806, the method includes forming a first PG positioned at a first acute corner of the parallelogram.

As shown at block 808, the method includes forming a second PG positioned at a second acute corner of the parallelogram.

In some embodiments, the method includes forming a VDD line positioned on a frontside of the SRAM bit cell and forming a VSS line positioned on a backside of the SRAM bit cell.

In some embodiments, the first PU and the second PU are on a top level of the SRAM bit cell and the first PD and the second PD are on a bottom level below the top level.

In some embodiments, the method includes forming a WL and a BL. In some embodiments, the first PG and the second PG are on the top level and the WL and BL are positioned on the frontside of the SRAM bit cell.

In some embodiments, the method includes forming a WL and a BL. In some embodiments, the first PG and the second PG are on the bottom level and the WL and BL are positioned on the backside of the SRAM bit cell.

In some embodiments, the method includes forming the bottom level (the bottom tier) of the SRAM bit cell first, over the surface of a wafer (not separately shown); then, the top level (top tier) is formed, followed by MOL and frontside BEOL elements. In some embodiments, the underlying wafer is bonded to another wafer and flipped. In some embodiments, the original wafer (substrate) is removed and backside MOL and BEOL are formed.

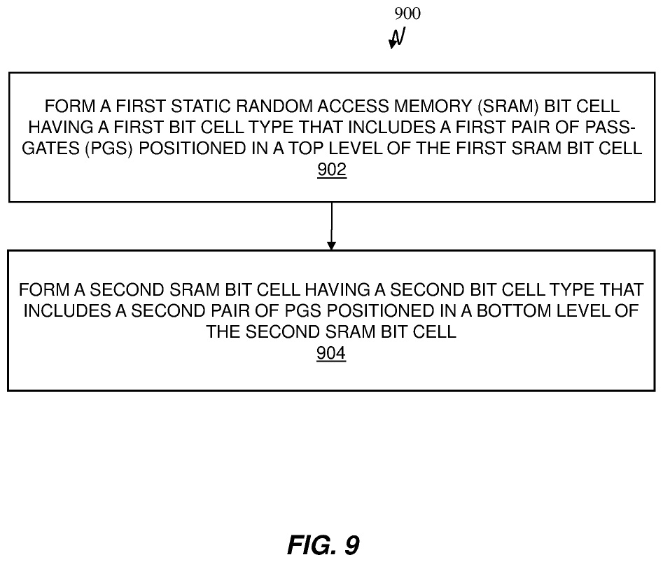

FIG. 9 depicts a flow diagram illustrating a method 900 for forming a semiconductor device according to one or more embodiments. The method 900 is described in reference to FIGS. 1-7 and may include additional blocks not depicted in FIG. 9. Although depicted in a particular order, the blocks depicted in FIG. 9 can be rearranged, subdivided, and/or combined.

As shown at block 902, the method includes forming a first SRAM bit cell having a first bit cell type. In some embodiments, the first bit cell type includes a first pair of PGs positioned in a top level of the first SRAM bit cell.

As shown at block 902, the method includes forming a second SRAM bit cell having a second bit cell type. In some embodiments, the second bit cell type includes a second pair of PGs positioned in a bottom level of the second SRAM bit cell.

In some embodiments, the first SRAM bit cell and the second SRAM bit cell are immediately adjacent bit cells. In some embodiments, a pass-gate of the first SRAM bit cell and a pass-gate of the second SRAM bit cell are vertically stacked in a same pass-gate area such that the first SRAM bit cell and the second SRAM bit cell partially overlap in a 3T footprint.

In some embodiments, each of the first SRAM bit cell and the second SRAM bit cell includes a first inverter positioned at a first obtuse corner of a parallelogram. The first inverter includes a first pull (PU vertically stacked over a first PD. A second inverter is positioned at a second obtuse corner of the parallelogram. The second inverter includes a second PU vertically stacked over a second PD. A first PG is positioned at a first acute corner of the parallelogram and a second PG is positioned at a second acute corner of the parallelogram.

In some embodiments, the first pair of PGs positioned in the top level of the first SRAM bit cell have a first polarity, and the second pair of PGs positioned in the bottom level of the second SRAM bit cell have a second polarity opposite the first polarity. In some embodiments, when the first pair of PGs and the second pair of PGs have opposite polarities in this manner, the first pair of PGs positioned in the top level (the top PGs) and the second pair of PGs positioned in the bottom level (the bottom PGs) have electrically isolated gates.

In some embodiments, the first SRAM bit cell includes a first WL and a first BL positioned on a frontside of the first SRAM bit cell, and the second SRAM bit cell includes a second WL and a second BL positioned on a backside of the second SRAM bit cell.

In some embodiments, the first pair of PGs positioned in the top level of the first SRAM bit cell and the second pair of PGs positioned in the bottom level of the second SRAM bit cell have a same polarity. In some embodiments, the method includes forming a WL positioned on a frontside of the semiconductor device, forming a first BL positioned on the frontside of the semiconductor device, and forming a second BL positioned on a backside of the semiconductor device. In some embodiments, when the first pair of PGs and the second pair of PGs have the same polarity in this manner, the top PGs and bottom PGs have electrically connected gates, and the WL is electrically connected to both the top PGs and bottom PGs.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the disclosure, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a static random access memory (SRAM) bit cell, the method comprising:
forming a first inverter positioned at a first obtuse corner of a parallelogram, the first inverter comprising a first pull-up transistor (PU) vertically stacked over a first pull-down transistor (PD);
forming a second inverter positioned at a second obtuse corner of the parallelogram, the second inverter comprising a second PU vertically stacked over a second PD;
forming a first pass-gate (PG) positioned at a first acute corner of the parallelogram; and
forming a second PG positioned at a second acute corner of the parallelogram.

2. The method of claim 1, further comprising:
forming a supply voltage (VDD) line positioned on a frontside of the SRAM bit cell; and
forming a source supply voltage (VSS) line positioned on a backside of the SRAM bit cell.

3. The method of claim 2, wherein the first PU and the second PU are on a top level of the SRAM bit cell and the first PD and the second PD are on a bottom level below the top level.

4. The method of claim 3, further comprising:
forming a word line (WL); and
forming a bit line (BL);
wherein the first PG and the second PG are on the top level; and
wherein the WL and BL are positioned on the frontside of the SRAM bit cell.

5. The method of claim 3, further comprising:
forming a word line (WL); and
forming a bit line (BL);
wherein the first PG and the second PG are on the bottom level; and
wherein the WL and BL are positioned on the backside of the SRAM bit cell.

6. A static random access memory (SRAM) bit cell comprising:
a first inverter positioned at a first obtuse corner of a parallelogram, the first inverter comprising a first pull-up transistor (PU) vertically stacked over a first pull-down transistor (PD);
a second inverter positioned at a second obtuse corner of the parallelogram, the second inverter comprising a second PU vertically stacked over a second PD;
a first pass-gate (PG) positioned at a first acute corner of the parallelogram; and
a second PG positioned at a second acute corner of the parallelogram.

7. The SRAM bit cell of claim 6, further comprising:
a supply voltage (VDD) line positioned on a frontside of the SRAM bit cell; and
a source supply voltage (VSS) line positioned on a backside of the SRAM bit cell.

8. The SRAM bit cell of claim 7, wherein the first PU and the second PU are on a top level of the SRAM bit cell and the first PD and the second PD are on a bottom level below the top level.

9. The SRAM bit cell of claim 8, further comprising:
a word line (WL); and
a bit line (BL);
wherein the first PG and the second PG are on the top level; and
wherein the WL and BL are positioned on the frontside of the SRAM bit cell.

10. The SRAM bit cell of claim 8, further comprising:
a word line (WL); and
a bit line (BL);
wherein the first PG and the second PG are on the bottom level; and
wherein the WL and BL are positioned on the backside of the SRAM bit cell.

11. A method for forming a semiconductor device, the method comprising:
forming a first static random access memory (SRAM) bit cell comprising a first bit cell type, the first bit cell type having a first pair of pass-gates (PGs) positioned in a top level of the first SRAM bit cell; and
forming a second SRAM bit cell comprising a second bit cell type, the second bit cell type having a second pair of PGs positioned in a bottom level of the second SRAM bit cell;
wherein the first SRAM bit cell and the second SRAM bit cell are immediately adjacent bit cells; and
wherein a pass-gate of the first SRAM bit cell and a pass-gate of the second SRAM bit cell are vertically stacked in a same pass-gate area such that the first SRAM bit cell and the second SRAM bit cell partially overlap in a three transistor (3T) footprint.

12. The method of claim 11, wherein each of the first SRAM bit cell and the second SRAM bit cell comprises:
a first inverter positioned at a first obtuse corner of a parallelogram, the first inverter comprising a first pull-up transistor (PU) vertically stacked over a first pull-down transistor (PD);
a second inverter positioned at a second obtuse corner of the parallelogram, the second inverter comprising a second PU vertically stacked over a second PD;
a first pass-gate (PG) positioned at a first acute corner of the parallelogram; and
a second PG positioned at a second acute corner of the parallelogram.

13. The method of claim 12, wherein the first pair of PGs positioned in the top level of the first SRAM bit cell have a first polarity, and the second pair of PGs positioned in the bottom level of the second SRAM bit cell have a second polarity opposite the first polarity.

14. The method of claim 13, wherein the first SRAM bit cell comprises a first word line (WL) and a first bit line (BL) positioned on a frontside of the first SRAM bit cell, and wherein the second SRAM bit cell comprises a second WL and a second BL positioned on a backside of the second SRAM bit cell.

15. The method of claim 12, wherein the first pair of PGs positioned in the top level of the first SRAM bit cell and the second pair of PGs positioned in the bottom level of the second SRAM bit cell have a same polarity, the method further comprising:
forming a word line (WL) positioned on a frontside of the semiconductor device;
forming a first bit line (BL) positioned on the frontside of the semiconductor device; and
forming a second BL positioned on a backside of the semiconductor device.

16. A semiconductor device comprising:
a first static random access memory (SRAM) bit cell comprising a first bit cell type, the first bit cell type having a first pair of pass-gates (PGs) positioned in a top level of the first SRAM bit cell; and
a second SRAM bit cell comprising a second bit cell type, the second bit cell type having a second pair of PGs positioned in a bottom level of the second SRAM bit cell;
wherein the first SRAM bit cell and the second SRAM bit cell are immediately adjacent bit cells; and
wherein a pass-gate of the first SRAM bit cell and a pass-gate of the second SRAM bit cell are vertically stacked in a same pass-gate area such that the first SRAM bit cell and the second SRAM bit cell partially overlap in a three transistor (3T) footprint.

17. The semiconductor device of claim 16, wherein each of the first SRAM bit cell and the second SRAM bit cell comprises:
a first inverter positioned at a first obtuse corner of a parallelogram, the first inverter comprising a first pull-up transistor (PU) vertically stacked over a first pull-down transistor (PD);
a second inverter positioned at a second obtuse corner of the parallelogram, the second inverter comprising a second PU vertically stacked over a second PD;
a first pass-gate (PG) positioned at a first acute corner of the parallelogram; and
a second PG positioned at a second acute corner of the parallelogram.

18. The semiconductor device of claim 17, wherein the first pair of PGs positioned in the top level of the first SRAM bit cell have a first polarity, and the second pair of PGs positioned in the bottom level of the second SRAM bit cell have a second polarity opposite the first polarity.

19. The semiconductor device of claim 18, wherein the first SRAM bit cell comprises a first word line (WL) and a first bit line (BL) positioned on a frontside of the first SRAM bit cell, and wherein the second SRAM bit cell comprises a second WL and a second BL positioned on a backside of the second SRAM bit cell.

20. The semiconductor device of claim 17, wherein the first pair of PGs positioned in the top level of the first SRAM bit cell and the second pair of PGs positioned in the bottom level of the second SRAM bit cell have a same polarity, the semiconductor device further comprising:
a word line (WL) positioned on a frontside of the semiconductor device;
a first bit line (BL) positioned on the frontside of the semiconductor device; and
a second BL positioned on a backside of the semiconductor device.

21. A static random access memory (SRAM) bit cell comprising:
a first inverter positioned at a first obtuse corner of a parallelogram, the first inverter comprising a first pull-down transistor (PD) vertically stacked over a first pull-up transistor (PU);
a second inverter positioned at a second obtuse corner of the parallelogram, the second inverter comprising a second PD vertically stacked over a second PU;
a first pass-gate (PG) positioned at a first acute corner of the parallelogram; and
a second PG positioned at a second acute corner of the parallelogram.

22. The SRAM bit cell of claim 21, further comprising:
a supply voltage (VDD) line positioned on a frontside of the SRAM bit cell; and
a source supply voltage (VSS) line positioned on a backside of the SRAM bit cell.

23. The SRAM bit cell of claim 22, wherein the first PD and the second PD are on a top level of the SRAM bit cell and the first PU and the second PU are on a bottom level below the top level.

24. The SRAM bit cell of claim 23, further comprising:
a word line (WL); and
a bit line (BL);
wherein the first PG and the second PG are on the top level; and
wherein the WL and BL are positioned on the frontside of the SRAM bit cell.

25. The SRAM bit cell of claim 23, further comprising:
a word line (WL); and
a bit line (BL);
wherein the first PG and the second PG are on the bottom level; and
wherein the WL and BL are positioned on the backside of the SRAM bit cell.
